(19) United States
(12) Patent Application Publication
(10) Pub. No.: US 2012/0175638 A1
(43) Pub. Date: Jul. 12, 2012

(54) SEMICONDUCTOR DEVICE

(75) Inventors: Toru HIYOSHI, Osaka-shi (JP); Hideto TAMASO, Osaka-shi (JP)

(73) Assignee: SUMITOMO ELECTRIC INDUSTRIES, LTD., Osaka-shi (JP)

(21) Appl. No.: 13/348,420

(22) Filed: Jan. 11, 2012

Related U.S. Application Data
(60) Provisional application No. 61/431,987, filed on Jan. 12, 2011.

(30) Foreign Application Priority Data
Jan. 12, 2011 (JP) 2011-003545

(51) Int. Cl. H01L 29/161

(52) U.S. Cl. 257/77; 257/E29.084

(57) ABSTRACT

A MOSFET includes: a silicon carbide substrate having a main surface having an off angle of not less than 50° and not more than 65° relative to a {0001} plane; an active layer; a gate oxide film; a p type body region having p type conductivity and formed to include a region of the active layer, the region being in contact with the gate oxide film; an n⁺ region having n type conductivity and formed in the p type body region to include a main surface of the active layer opposite to the silicon carbide substrate; and a source contact electrode formed on the active layer in contact with the n⁺ region, the p type body region having a p type impurity density of 5×10¹⁷ cm⁻³ or greater, the source contact electrode and the p type body region being in direct contact with each other.

### BACKGROUND OF THE INVENTION

1. Field of the Invention

The present invention relates to a semiconductor device, more particularly, a semiconductor device achieving both sufficient channel mobility and reduced manufacturing cost of the semiconductor device.

2. Description of the Background Art

In recent years, in order to achieve high breakdown voltage, low loss, and utilization of semiconductor devices under a high temperature environment, silicon carbide has begun to be adopted as a material for a semiconductor device. Silicon carbide is a wide band gap semiconductor having a band gap larger than that of silicon, which has been conventionally widely used as a material for semiconductor devices. Hence, by adopting silicon carbide as a material for a semiconductor device, the semiconductor device can have a high breakdown voltage, reduced on-resistance, and the like. Further, the semiconductor device thus adopting silicon carbide as its material has characteristics less deteriorated even under a high temperature environment than those of a semiconductor device adopting silicon as its material, advantageously.

Various studies have been conducted to adjust a threshold voltage and improve channel mobility in semiconductor devices adopting silicon carbide as their material as described above and controlling existence/non-existence of an inversion layer in a channel region in accordance with a predetermined threshold voltage so as to conduct and interrupt a current (for example, see Sei-Hyung Ryu et al., “Critical Issues for MOS Based Power Devices in 4H-SiC”, Materials Science Forum, 2009, Vols. 615-617, p 743-748). Examples of such semiconductor devices include a MOSFET (Metal Oxide Semiconductor Field Effect Transistor), an IGBT (Insulated Gate Bipolar Transistor), and the like.

Here, a semiconductor device such as a MOSFET or an IGBT with an N channel is provided with a p type body region having p type conductivity. In the p type body region, a channel region is formed. In order to fix the potential of the p type body region, it is necessary to secure an ohmic contact between the p type body region and an electrode formed on the p type body region. This ohmic contact can be attained by increasing density (doping density) of a p type impurity (such as B (boron) or Al (aluminum)) in the p type body region. However, when securing the ohmic contact in this way, channel mobility will be significantly decreased, disadvantageously. This is because the dopant with such an increased doping density causes noticeable scattering of electrons. In view of this, the p type body region is set to have a doping density of, for example, approximately 1×10¹⁶ cm⁻³ to 4×10¹⁶ cm⁻³. Further, in order to secure the ohmic contact between the electrode and the p type body region, there is adopted a structure which employs a region (p⁺ region) formed at a region other than the channel region in the p type body region and having a doping density higher than the p type body region. The formation of such a p⁺ region requires processes such as film formation of a mask material, photolithography, dry etching, and ion implantation. Accordingly, when the above-described structure is employed, the manufacturing cost of the semiconductor device will be increased. This makes it difficult for the conventional semiconductor device to achieve both sufficient channel mobility and reduced manufacturing cost of the semiconductor device, disadvantageously.

### SUMMARY OF THE INVENTION

The present invention is made in view of the foregoing problem, and has its object to provide a method for manufacturing a semiconductor device achieving both sufficient channel mobility and reduced manufacturing cost.

A semiconductor device according to the present invention includes: a silicon carbide substrate having a main surface having an off angle of not less than 50° and not more than 65° relative to a {0001} plane; an epitaxial growth layer formed on the main surface; an insulating film formed on and in contact with the epitaxial growth layer; a p type body region having p type conductivity and formed to include a region of the epitaxial growth layer, the region being in contact with the insulating film; an n type contact region having n type conductivity and formed in the p type body region to include a main surface of the epitaxial growth layer opposite to the silicon carbide substrate; and a contact electrode formed on the epitaxial growth layer in contact with the n type contact region. The p type body region has a p type impurity density of 5×10¹⁷ cm⁻³ or greater, and the contact electrode and the p type body region are in direct contact with each other.

The present inventor has obtained the following findings and arrived at the present invention as a result of detailed study on schemes for achieving both sufficient channel mobility and reduced manufacturing cost of a semiconductor device. In a conventional semiconductor device adopting silicon carbide as its material, a silicon carbide substrate is employed to have a main surface having an off angle of approximately 8° or smaller relative to the {0001} plane. On such a main surface, an epitaxial growth layer and the like are formed to fabricate a semiconductor device. In such a semiconductor device, it is difficult to achieve both sufficient channel mobility and reduced manufacturing cost of the semiconductor device as described above. However, according to the study conducted by the present inventor, it has been found that when adapting the main surface of the silicon carbide substrate to have an off angle of a predetermined range relative to the {0001} plane, the trade-off relation between increase of the doping density of the p type body region and improvement of the channel mobility can be significantly eased.

More specifically, by employing the following structure, the channel mobility is significantly restrained from being decreased even when the doping density of the p type body region is increased. That is, in the structure, a silicon carbide substrate having a main surface having an off angle of not less than 50° and not more than 65° relative to the {0001} plane is used as the silicon carbide substrate, then an epitaxial growth layer is formed on the main surface thereof, and then a p type impurity (B, Al, or the like) is introduced into this epitaxial growth layer to form a p type body region. With such a feature, the doping density of the p type body region is increased to secure the ohmic contact between the contact electrode and the p type body region while restraining decrease of the channel mobility, whereby no p⁺ region needs to be formed. This leads to reduced manufacturing cost.

In other words, the semiconductor device of the present invention employs the structure in which the epitaxial growth layer is formed on the silicon carbide substrate having the main surface having an off angle of not less than 50° and not more than 65° relative to the {0001} plane, so as to restrain the mobility from being decreased even when the p type body region is adapted to have a p type impurity density of 5×10¹⁷ cm⁻³ or greater and so as to fix the potential of the p type body region by means of the direct contact between the contact electrode and the p type body region. Because no p⁺ region is accordingly formed between the contact electrode and the p type body region, manufacturing cost is reduced. Thus, according to the semiconductor device of the present invention, there can be provided a semiconductor device achieving both sufficient channel mobility and reduced manufacturing cost.

In the semiconductor device, the main surface may have an off orientation forming an angle of 5° or smaller relative to a <01-10> direction.

The <01-10> direction is a representative off orientation in a silicon carbide substrate. Variation in the off orientation resulting from variation in a slicing process of the process of manufacturing the substrate is adapted to be 5° or smaller, which allows an epitaxial growth layer to be formed readily on the silicon carbide substrate.

In the semiconductor device, the main surface may have an off angle of not less than −3° and not more than 5° relative to a {03-38} plane in the <01-10> direction.

Accordingly, the channel mobility can be further improved. Here, setting the off angle at not less than −3° and not more than +5° relative to the plane orientation of {03-38} is based on a fact that particularly high channel mobility was obtained in this set range as a result of inspecting a relation between the channel mobility and the off angle.

Further, the “off angle relative to the {03-38} plane in the <01-10> direction” refers to an angle formed by an orthogonal projection of a normal line of the above-described main surface to a flat plane defined by the <01-10> direction and the <0001> direction, and a normal line of the {03-38} plane. The sign of positive value corresponds to a case where the orthogonal projection approaches in parallel with the <01-10> direction whereas the sign of negative value corresponds to a case where the orthogonal projection approaches in parallel with the <0001> direction.

It should be noted that the main surface preferably has a plane orientation of substantially {03-38}, and the main surface more preferably has a plane orientation of {03-38}. Here, the expression “the main surface has a plane orientation of substantially {03-38}” is intended to encompass a case where the plane orientation of the main surface of the substrate is included in a range of off angle such that the plane orientation can be substantially regarded as {03-38} in consideration of processing accuracy of the substrate. In this case, the range of off angle is, for example, a range of off angle of ±2° relative to {03-38}. Accordingly, the above-described channel mobility can be further improved.

In the semiconductor device, the main surface may have an off orientation forming an angle of 5° or smaller relative to a <−2110> direction.

The <−2110> direction is a representative off orientation in a silicon carbide substrate, as with the <01-10> direction. Variation in the off orientation resulting from variation in a slicing process of the process of manufacturing the substrate is adapted to be ±5°, which allows an epitaxial growth layer to be formed readily on the silicon carbide substrate.

In the semiconductor device, the main surface may be a surface corresponding to a carbon plane side of silicon carbide constituting the silicon carbide substrate.

In this way, the channel mobility can be further improved. Here, the (0001) plane of single-crystal silicon carbide of hexagonal crystal is defined as the silicon plane whereas the (000-1) plane is defined as the carbon plane. In other words, when employing the configuration in which the off orientation of the main surface forms an angle of 5° or smaller relative to the <01-10> direction, the channel mobility is further improved by adapting the main surface to correspond to a plane close to the (0-33-8) plane.

In the semiconductor device, the p type body region may have a p type impurity density of 1×10²⁰ cm⁻³ or smaller.

Even when the p type impurity density of the p type body region is thus set at 1×10²⁰ cm⁻³ or smaller, the potential of the p type body can be sufficiently fixed by the contact electrode. Meanwhile, if a doping density exceeding 1×10²⁰ cm⁻³ is adopted, crystallinity may be deteriorated, disadvantageously.

In the semiconductor device, the p type body region may have a p type impurity density of 5×10¹⁸ cm⁻³ or smaller.

Even when the p type impurity density of the p type body region is thus set at 5×10¹⁸ cm⁻³ or smaller, the potential of the p type body can be fixed by the contact electrode. Further, with the p type impurity density equal to or smaller than 5×10¹⁸ cm⁻³, higher channel mobility can be achieved.

In the semiconductor device, the contact electrode may contain at least one element selected from a group consisting of Ti, Al, Si, and Ni. Further, in the semiconductor device, the contact electrode may be made of TiAlSi, TiAlNi, TiAl, or NiSi. By employing such a contact electrode, the contact resistance between the contact electrode and the p type body is reduced, thereby fixing the potential of the p type body more readily.

In the semiconductor device, a contact resistance between the contact electrode and the n type contact region may be 1×10⁻⁴ Ωcm² or smaller. Accordingly, on-resistance of the semiconductor device can be further reduced.

In the semiconductor device, a contact resistance between the contact electrode and the p type body region may be 1 Ωcm² or smaller. In this way, the potential of the p type body region can be fixed more securely.

As apparent from the description above, according to the semiconductor device of the present invention, there can be provided a semiconductor device achieving both sufficient channel mobility and reduced manufacturing cost of the semiconductor device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing a structure of a MOSFET in a first embodiment.

FIG. 2 is a flowchart schematically showing a method for manufacturing the MOSFET in the first embodiment.

FIG. 3 is a schematic cross sectional view for illustrating the method for manufacturing the MOSFET in the first embodiment.

FIG. 4 is a schematic cross sectional view for illustrating the method for manufacturing the MOSFET in the first embodiment.

FIG. 5 is a schematic cross sectional view for illustrating the method for manufacturing the MOSFET in the first embodiment.

FIG. 6 is a schematic cross sectional view for illustrating the method for manufacturing the MOSFET in the first embodiment.

FIG. 7 is a schematic cross sectional view for illustrating the method for manufacturing the MOSFET in the first embodiment.

FIG. 8 is a schematic cross sectional view showing a structure of an IGBT in a second embodiment.

FIG. 9 is a flowchart schematically showing a method for manufacturing the IGBT in the second embodiment.

FIG. 10 is a schematic cross sectional view for illustrating the method for manufacturing the IGBT in the second embodiment.

FIG. 11 is a schematic cross sectional view for illustrating the method for manufacturing the IGBT in the second embodiment.

FIG. 12 is a schematic cross sectional view for illustrating the method for manufacturing the IGBT in the second embodiment.

FIG. 13 is a schematic cross sectional view for illustrating the method for manufacturing the IGBT in the second embodiment.

FIG. 14 is a schematic cross sectional view for illustrating the method for manufacturing the IGBT in the second embodiment.

### DESCRIPTION OF THE PREFERRED EMBODIMENTS

The following describes embodiments of the present invention with reference to figures. It should be noted that in the below-mentioned figures, the same or corresponding portions are given the same reference characters and are not described repeatedly. Further, in the present specification, an individual orientation is represented by [ ], a group orientation is represented by < >, and an individual plane is represented by ( ) and a group plane is represented by { }. In addition, a negative index is supposed to be crystallographically indicated by putting “-” (bar) above a numeral, but is indicated by putting the negative sign before the numeral in the present specification.

### First Embodiment

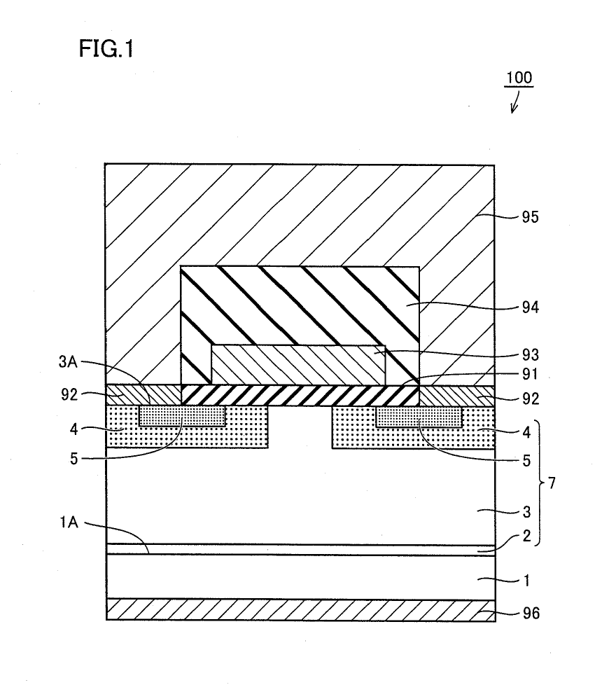

First, a first embodiment, which is one embodiment of the present invention, will be described. Referring to FIG. 1, a MOSFET 100, which is a semiconductor device in the present embodiment, includes: a silicon carbide substrate 1 having n type conductivity; a buffer layer 2 made of silicon carbide and having n type conductivity; a drift layer 3 made of silicon carbide and having n type conductivity; a pair of p type body regions 4 each having p type conductivity; and n⁺ regions 5 each having n type conductivity.

Buffer layer 2 is formed on one main surface 1A of silicon carbide substrate 1, and contains an n type impurity and therefore has n type conductivity. Drift layer 3 is formed on buffer layer 2, and contains an n type impurity and therefore has n type conductivity. The n type impurity contained in drift layer 3 is, for example, N (nitrogen), and is contained therein at a concentration (density) lower than that of the n type impurity contained in buffer layer 2. Buffer layer 2 and drift layer 3 constitute an epitaxial growth layer formed on one main surface 1A of silicon carbide substrate 1.

The pair of p type body regions 4 are formed to be separated from each other so as to include main surface 3A of the epitaxial growth layer opposite to its main surface facing silicon carbide substrate 1. Each of p type body regions 4 contains a p type impurity (impurity having p type conductivity) and therefore has p type conductivity. The p type impurity thus contained in p type body region 4 is, for example, aluminum (Al), boron (B), or the like.

N⁺ regions 5, which include main surface 3A described above, are formed within the pair of p type regions 4 and are surrounded by p type body regions 4. Each of n⁺ regions 5 contains an n type impurity such as P at a concentration (density) higher than that of the n type impurity contained in drift layer 3. Buffer layer 2, drift layer 3, p type regions 4, and n⁺ regions 5 constitute an active layer 7.

Referring to FIG. 1, MOSFET 100 further includes: a gate oxide film 91 serving as a gate insulating film; a gate electrode 93; a pair of source contact electrodes 92; an interlayer insulating film 94; a source wire 95; and a drain electrode 96.

Gate oxide film 91 is formed on and in contact with main surface 3A so as to extend from a location on the upper surface of one n⁺ region 5 to a location on the upper surface of the other n⁺ region 5. Gate oxide film 91 is made of, for example, silicon dioxide (SiO₂).

Gate electrode 93 is disposed in contact with gate oxide film 91 so as to extend from a location over one n⁺ region 5 to a location over the other n⁺ region 5. Further, gate electrode 93 is made of a conductor such as polysilicon having an impurity added thereto or Al.

Source contact electrodes 92 are disposed in contact with main surface 3A and extend from respective locations on the pair of n⁺ regions 5 in the directions getting away from gate oxide film 91. Each of source contact electrodes 92 may contain at least one element selected from a group consisting of, for example, Ti, Al, Si, and Ni. More specifically, source contact electrode 92 is made of, for example, TiAlSi, TiAlNi, TiAl, or NiSi. In this way, source contact electrode 92 forms an ohmic contact with n⁺ region 5.

Interlayer insulating film 94 is formed to surround gate electrode 93 over main surface 3A of drift layer 3, and extends from a location over one p type body region 4 to a location over the other p type body 4. Interlayer insulating film 94 is made of, for example, silicon dioxide (SiO₂), which is an insulator.

Source wire 95 surrounds interlayer insulating film 94 over main surface 3A, and extends onto the upper surfaces of source contact electrodes 92. Source wire 95 is made of a conductor such as Al, and is electrically connected to n⁺ regions 5 via source contact electrodes 92.

Drain electrode 96 is formed in contact with the main surface of silicon carbide substrate 1 opposite to the side at which drift layer 3 is formed. Drain electrode 96 is made of the same material as that of each of source contact electrodes 92, and is electrically connected to silicon carbide substrate 1.

The following describes operations of MOSFET 100. Referring to FIG. 1, when drain electrode 96 is fed with a voltage while gate electrode 93 has a voltage smaller than a threshold voltage, i.e., while it is in the OFF state, a pn junction of p type body region 4 and drift layer 3 just below gate oxide film 91 is reverse-biased. Accordingly, MOSFET 100 is in the non-conductive state. On the other hand, when gate electrode 93 is fed with a voltage equal to or greater than the threshold voltage, an inversion layer is formed in a channel region near each of locations at which p type body regions 4 make contact with gate oxide film 91. As a result, n⁺ regions 5 and drift layer 3 are electrically connected to one another, whereby a current flows between source wire 95 and drain electrode 96.

Here, in MOSFET 100, each of p type body regions 4 has a p type impurity density of 5×10¹⁷ cm⁻³ or greater, and main surface 1A of silicon carbide substrate 1 has an off angle of not less than 50° and not more than 65° relative to a {0001} plane. With the off angle of not less than 50° and not more than 65°, mobility (channel mobility) of carriers (electrons) can be restrained from decreasing in the channel region even when p type body region 4 is formed to have a high doping density such as the p type impurity density of 5×10¹⁷ cm⁻³ or greater. Further, source contact electrode 92 and p type body region 4 are in direct contact with each other, thus fixing the potential of p type body region 4. Further, no p⁺ region for fixing the potential of p type body region 4 is formed. Accordingly, MOSFET 100 becomes a semiconductor device achieving both sufficient channel mobility and reduced manufacturing cost.

Further, main surface 1A of silicon carbide substrate 1 has an off orientation forming an angle of 5° or smaller relative to a <01-10> direction. This allows the epitaxial growth layer (buffer layer 2 and drift layer 3) to be readily formed on silicon carbide substrate 1.

Further, main surface 1A preferably has an off angle of not less than −3° and not more than 5° relative to a {03-38} plane in the <01-10> direction. More preferably, main surface 1A corresponds to substantially the {03-38} plane. Accordingly, the channel mobility can be further improved.

Meanwhile, in MOSFET 100, the off orientation of main surface 1A may form an angle of 5° or smaller relative to a <−2110> direction. This facilitates formation of the epitaxial growth layer (buffer layer 2 and drift layer 3) on silicon carbide substrate 1.

Further, main surface 1A is preferably a surface corresponding to a carbon plane side of silicon carbide constituting silicon carbide substrate 1. Accordingly, the channel mobility can be further improved.

Further, p type body region 4 preferably has a p type impurity density of 1×10²⁰ cm⁻³ or smaller. Accordingly, crystallinity can be restrained from being deteriorated.

Further, p type body region 4 may have a p type impurity density of 5×10¹⁸ cm⁻³ or smaller. Accordingly, higher channel mobility can be achieved.

Further, MOSFET 100 may be of normally-off type. Even when the doping density of the p type body region is increased to such an extent that MOSFET 100 serves as normally-off type, the channel mobility is sufficiently restrained in MOSFET 100 described above.

Further, in MOSFET 100, gate electrode 93 may be made of p type polysilicon. In this way, the threshold voltage can be readily shifted to increase, whereby MOSFET 100 readily becomes normally-off type.

Further, in MOSFET 100, gate electrode 93 may be made of n type polysilicon. In this way, switching speed of MOSFET 100 can be improved.

Further, in MOSFET 100, a contact resistance between source contact electrode 92 and n⁺ region 5 serving as an n type contact region is 1×10⁻⁴ Ωcm² or smaller. In this way, on-resistance of MOSFET 100 can be further reduced.

In MOSFET 100, the contact resistance between source contact electrode 92 and p type body region 4 is preferably 1 Ωcm² or smaller. In this way, the potential of p type body region 4 can be fixed more securely.

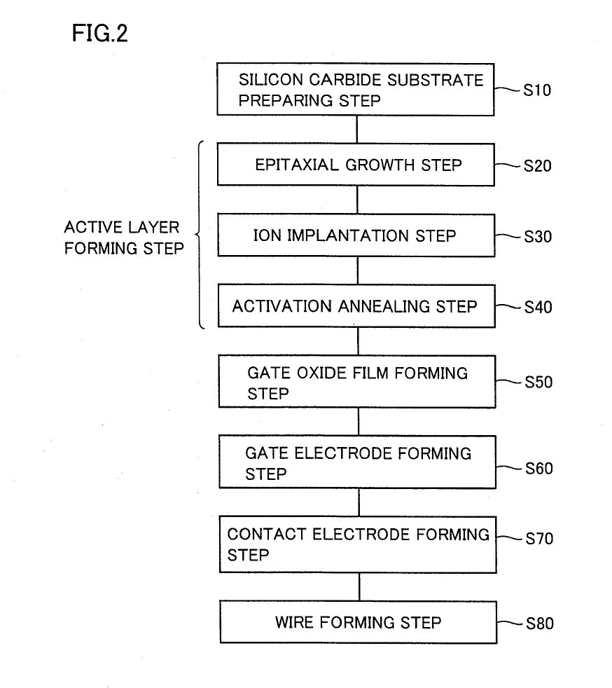

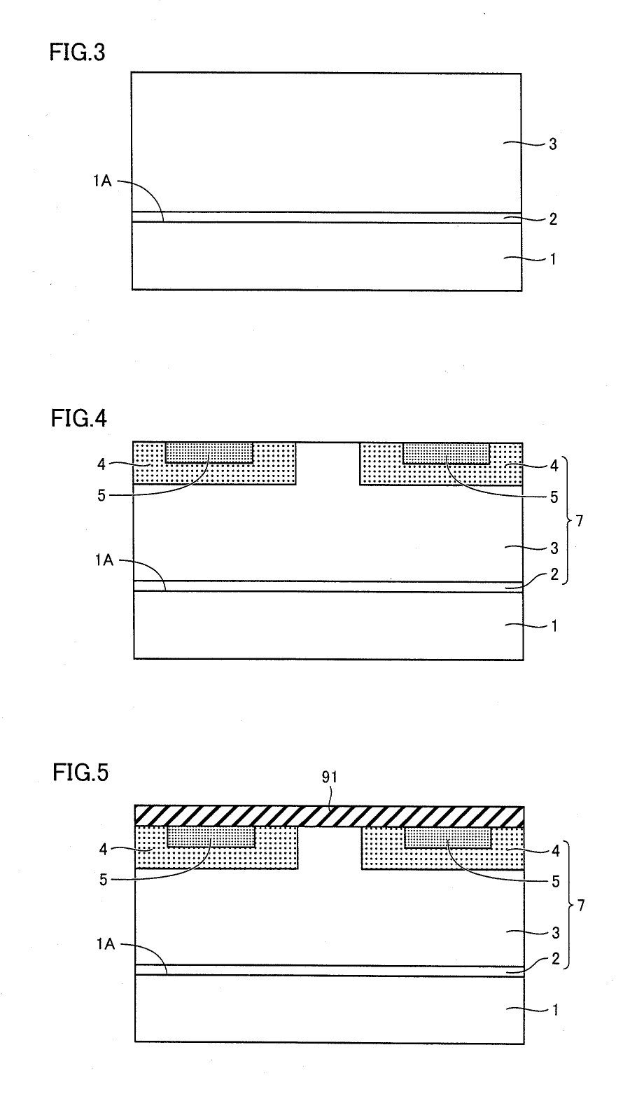

The following describes one exemplary method for manufacturing MOSFET 100 in the first embodiment, with reference to FIG. 2 to FIG. 7. Referring to FIG. 2, in the method for manufacturing MOSFET 100 in the present embodiment, a silicon carbide substrate preparing step is first performed as a step (S10). In this step (S10), referring to FIG. 3, silicon carbide substrate 1 is prepared which has main surface 1A having an off angle of not less than 50° and not more than 65° relative to the {0001} plane.

Next, as a step (S20), an epitaxial growth step is performed. In this step (S20), referring to FIG. 3, buffer layer 2 and drift layer 3 are sequentially formed on/over one main surface 1A of silicon carbide substrate 1 by means of epitaxial growth.

Next, as a step (S30), an ion implantation step is performed. In this step (S30), referring to FIG. 3 and FIG. 4, ion implantation is performed to form p type body regions 4, first. Specifically, for example, Al (aluminum) ions are introduced into drift layer 3, thereby forming p type body regions 4. On this occasion, the ion implantation is performed to allow each of the p type body regions to have a p type impurity density of 5×10¹⁷ cm⁻³ or greater. Next, ion implantation is performed to form n⁺ regions 5. Specifically, for example, P (phosphorus) ions are implanted into p type body regions 4, thereby forming n⁺ regions 5 within p type body regions 4. The ions can be implanted using a mask layer formed on the main surface of drift layer 3, made of silicon dioxide (SiO₂), and having openings at desired regions for the ion implantation, for example. Further, in MOSFET 100, no p⁺ region for fixing the potential of p type body region 4 is formed. Accordingly, manufacturing cost can be reduced.

Next, as a step (S40), an activation annealing step is performed. In this step (S40), for example, heat treatment is performed by heating them to 1700° C. in an inert gas atmosphere such as argon for 30 minutes. Accordingly, the impurities implanted in the above-described step (S30) are activated.

Next, as a step (S50), a gate oxide film forming step is performed. In this step (S50), referring to FIG. 4 and FIG. 5, heat treatment is performed by heating them to, for example, 1300° C. in an oxygen atmosphere for 60 minutes, thereby forming oxide film (gate oxide film) 91.

After this step (S50), a NO annealing step may be performed. In this NO annealing step, heat treatment is performed in nitrogen monoxide (NO) gas, which is employed as atmospheric gas. This heat treatment is performed, for example, at a temperature of not less than 1100° C. and not more than 1300° C. for approximately one hour. With such heat treatment, nitrogen atoms are introduced into an interface region between oxide film 91 and drift layer 3. Accordingly, interface states are restrained from being formed at the interface region between oxide film 91 and drift layer 3, which leads to improved channel mobility in MOSFET 100 to be finally obtained. It should be noted that a process may be employed which uses, as the atmospheric gas, other gas allowing nitrogen atoms to be introduced into the interface region between oxide film 91 and drift layer 3, instead of the NO gas.

An Ar annealing step is preferably performed just after the NO annealing step. This Ar annealing step employs argon (Ar) gas as atmospheric gas. In this atmospheric gas, heat treatment is performed to heat them. This heat treatment can be performed, for example, for approximately one hour at a temperature higher than the heating temperature in the above-described NO annealing step and smaller than the melting point of oxide film 91. With such heat treatment, interface states are restrained from being formed at the interface region between oxide film 91 and drift layer 3, thereby achieving improved channel mobility of MOSFET 100 to be finally obtained. It should be noted that a process may be employed in which other inert gas such as nitrogen gas is used as the atmospheric gas instead of the Ar gas.

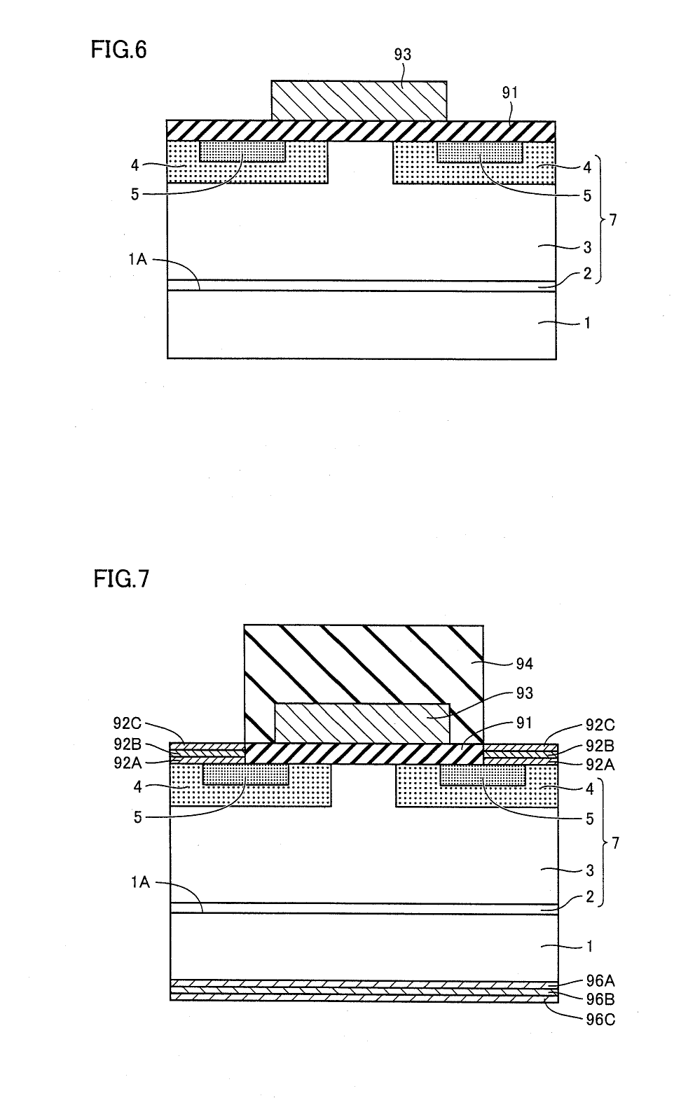

Next, as a step (S60), a gate electrode forming step is performed. In this step (S60), referring to FIG. 5 and FIG. 6, a polysilicon film, which is a conductor having an impurity added thereto at a high concentration, is first formed on oxide film 91 using, for example, a CVD (Chemical Vapor Deposition) method. Then, a mask layer is formed on the polysilicon film so as to correspond to a desired shape of gate electrode 93. Then, RIE is performed to form gate electrode 93, for example.

Next, as a step (S70), a contact electrode forming step is performed. In this step (S70), referring to FIG. 6 and FIG. 7, an insulating film made of an insulator such as silicon dioxide is formed using for example the CVD method so as to cover gate electrode 93 and oxide film 91. Next, a mask layer is formed on the insulating film so as to correspond to a desired shape of source contact electrode 92. Then, for example, RIE is provided to portions of the insulating film and oxide film 91 which correspond to regions in which the source contact electrodes are to be formed. In this way, the remaining insulating film serves as interlayer insulating film 94.

Further, a titanium film 92A, an aluminum film 92B, and a silicon film 92C are sequentially formed on each of the region from which the insulating film and oxide film 91 have been removed and the main surface of silicon carbide substrate 1 opposite to buffer layer 2. Then, annealing is performed to heat them in an inert gas atmosphere such as argon, thereby alloying titanium, aluminum, and silicon. In this way, source contact electrodes 92 and drain electrode 96 each made of TiAlSi are formed (see FIG. 1). It should be noted that source contact electrodes 92 and drain electrode 96 are not limited to those made of TiAlSi and may be made of NiSi, for example. In this case, instead of titanium film 92A, aluminum film 92B, and silicon film 92C described above, a nickel layer is formed and then alloyed with silicon contained in silicon carbide by means of annealing, thereby fabricating source contact electrode 92.

Next, as a step (S80), a wire forming step is performed. In this step (S80), for example, referring to FIG. 1, using a deposition method, source wire 95 made of Al that is a conductor is formed to surround interlayer insulating film 94 over main surface 3A and extend to the locations over and on the upper surfaces of n⁺ regions 5 and source contact electrodes 92. With the above-described procedure, MOSFET 100 in the present embodiment is completed.

### Second Embodiment

The following describes another embodiment of the present invention, i.e., a second embodiment. An IGBT 200, which is a semiconductor device of the second embodiment, has a structure similar to that of MOSFET 100 in the first embodiment, in terms of the plane orientation of the silicon carbide substrate, the p type impurity density of the p type body region, and the omission of the p⁺ region in the first embodiment. Hence, IGBT 200 provides an effect similar thereto.

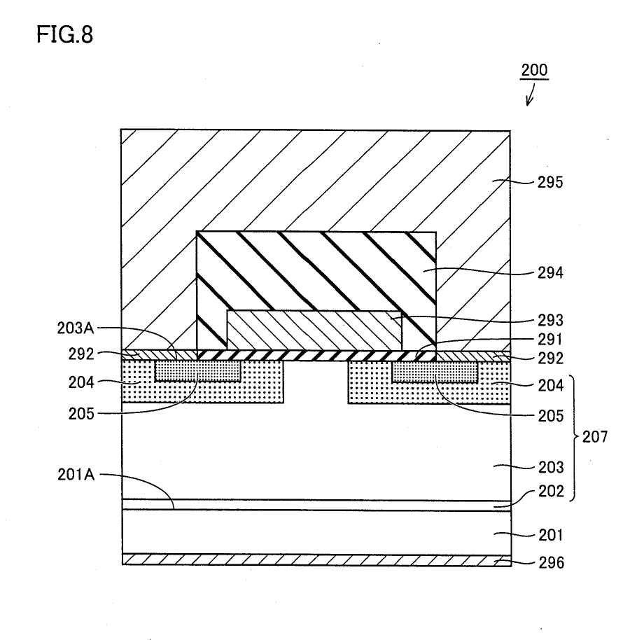

Specifically, referring to FIG. 8, IGBT 200, which is a semiconductor device in the present embodiment, includes: a silicon carbide substrate 201 having p type conductivity; a buffer layer 202 (which may have n type or p type conductivity); a drift layer 203 made of silicon carbide and having n type conductivity; and a pair of p type body regions 204 each having p type conductivity; and n⁺ regions 205 each having n type conductivity.

Buffer layer 202 is formed on one main surface 201A of silicon carbide substrate 201, and contains an impurity at a concentration higher than that in drift layer 203. Drift layer 203 is formed on buffer layer 202, and contains an n type impurity and therefore has n type conductivity. Buffer layer 202 and drift layer 203 constitutes an epitaxial growth layer formed on one main surface 201A of silicon carbide substrate 201.

The pair of p type body regions 204 are formed to be separated from each other so as to include main surface 203A of drift layer 203 opposite to its main surface facing silicon carbide substrate 201. Each of p type body regions 204 contains a p type impurity and therefore has p type conductivity. The p type impurity thus contained in p type body region 204 is for example, aluminum (Al), boron (B), or the like.

N⁺ regions 205, which include main surface 203A described above, are formed within the pair of p type body regions 204 and are surrounded by p type body regions 204. Each of n⁺ regions 205 contains an n type impurity such as P at a concentration (density) higher than that of the n type impurity contained in drift layer 203. Buffer layer 202, drift layer 203, p type body regions 204, and n⁺ regions 205 constitute an active layer 207.

Further, referring to FIG. 8, IGBT 200 further includes: a gate oxide film 291 serving as a gate insulating film; a gate electrode 293; a pair of emitter contact electrodes 292; an interlayer insulating film 294; an emitter wire 295; and a collector electrode 296.

Gate oxide film 291 is formed on and in contact with main surface 203A so as to extend from a location on the upper surface of one n⁺ region 205 to a location on the upper surface of the other n⁺ region 205. Gate oxide film 291 is made of, for example, silicon dioxide (SiO₂).

Gate electrode 293 is disposed on and in contact with gate oxide film 291 so as to extend from a location over one n⁺ region 205 to a location over the other n⁺ region 205. Further, gate electrode 293 is made of a conductor such as polysilicon having an impurity added thereto or Al.

Emitter contact electrodes 292 are formed on the pair of n⁺ regions 205 and are disposed in contact with main surface 203A. Further, each of emitter contact electrodes 292 is made of, for example, nickel silicide (NiSi) or the like.

Interlayer insulating film 294 is formed to surround gate electrode 293 over main surface 203A of drift layer 203, and extends from a location over one p type body region 204 to a location over the other p type body region 204. Interlayer insulating film 294 is made of, for example, silicon dioxide (SiO₂), which is an insulator.

Emitter wire 295 surrounds interlayer insulating film 294 over main surface 203A of drift layer 203, and extends onto the upper surfaces of emitter contact electrodes 292. Emitter wire 295 is made of a conductor such as Al, and is electrically connected to n⁺ regions 205 via emitter contact electrodes 292.

Collector electrode 296 is formed in contact with the main surface of silicon carbide substrate 201 opposite to the side at which drift layer 203 is formed. Collector electrode 296 is made of, for example, nickel silicide (NiSi). Collector electrode 296 is electrically connected to silicon carbide substrate 201.

The following describes operations of IGBT 200. Referring to FIG. 8, when a voltage applied to gate electrode 293 exceeds a threshold value, an inversion layer is formed in each of p type body regions 204 making contact with gate oxide film 291 disposed below gate electrode 293, thereby electrically connecting n⁺ region 205 and drift layer 203 to each other. Accordingly, electrons are injected from each of n⁺ regions 205 to drift layer 203. Correspondingly, positive holes are supplied from silicon carbide substrate 201 to drift layer 203 through buffer layer 202. As a result, IGBT 200 is brought into the ON state. Accordingly, conductivity modulation takes place in drift layer 203 to decrease a resistance between emitter contact electrode 292 and collector electrode 296, thus allowing a current to flow therein. On the other hand, when the voltage applied to gate electrode 293 is equal to or smaller than the threshold value, the inversion layer is not formed. Hence, the reverse-biased state is maintained between drift layer 203 and p type body region 204. As a result, IGBT 200 is brought into the OFF state, whereby no current flows therein.

Here, in IGBT 200, p type body region 204 has a p type impurity density of 5×10¹⁷ cm⁻³ or greater, and has an off angle of not less than 50° and not more than 65° relative to the {0001} plane of main surface 201A of silicon carbide substrate 201. With the off angle of not less than 50° and not more than 65°, mobility (channel mobility) of carriers (electrons) can be restrained from decreasing in the channel region even when p type body region 204 is formed to have a high doping density such as the p type impurity density of 5×10¹⁷ cm³ or greater. Further, emitter contact electrode 292 and p type body region 204 are in direct contact with each other, thus fixing the potential of p type body region 204. Further, no p⁺ region for fixing the potential of p type body region 204 is formed. Accordingly, IGBT 200 is a semiconductor device achieving both sufficient channel mobility and reduced manufacturing cost of the semiconductor device.

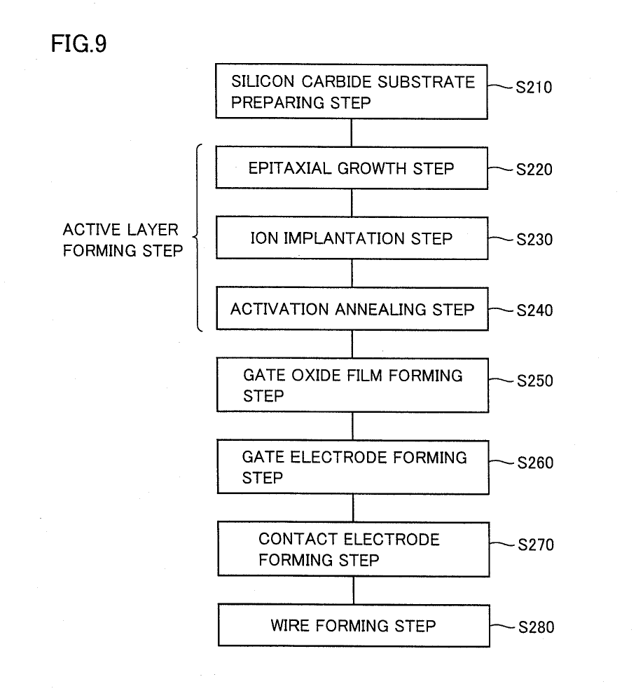

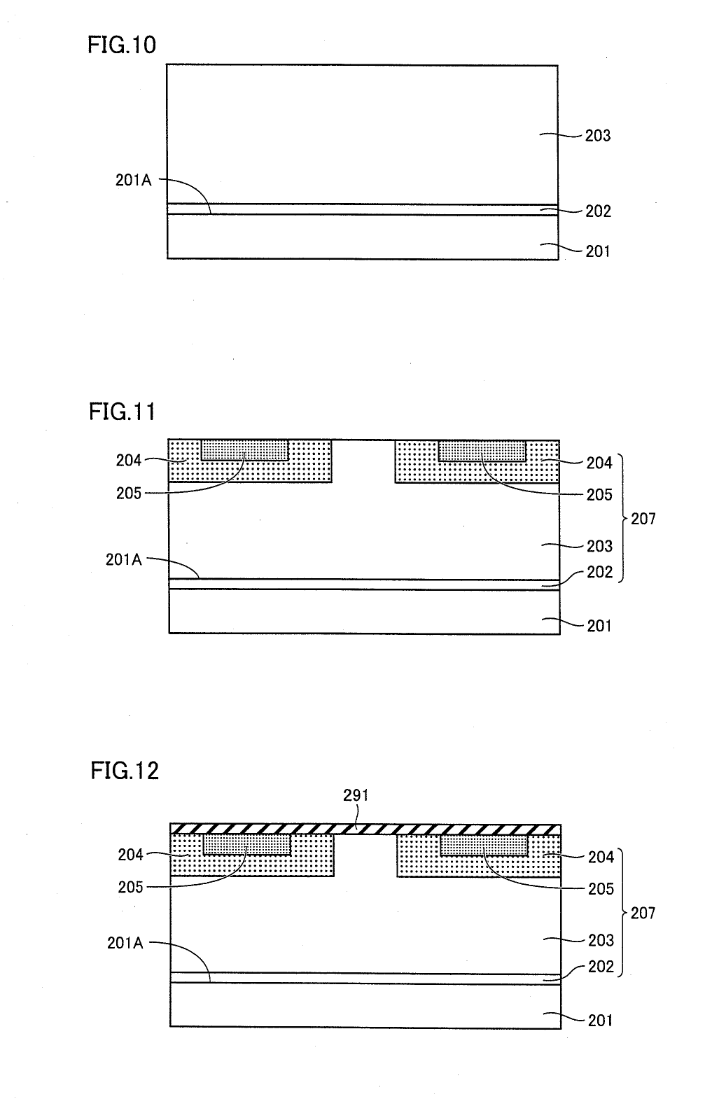

The following describes one exemplary method for manufacturing IGBT 200 in the second embodiment, with reference to FIG. 9-FIG. 14. Referring to FIG. 9, in the method for manufacturing IGBT 200 in the present embodiment, a silicon carbide substrate preparing step is first performed as a step (S210). In this step (S210), referring to FIG. 10, as with step (S10) of the first embodiment, silicon carbide substrate 201 is prepared which has main surface 201A having an off angle of not less than 50° and not more than 65° relative to the {0001} plane.

Next, as a step (S220), an epitaxial growth step is performed. In this step (S220), referring to FIG. 10, as with step (S20) of the first embodiment, buffer layer 202 and drift layer 203 are sequentially formed by epitaxial growth on one main surface 201A of silicon carbide substrate 201.

Next, as a step (S230), an ion implantation step is performed. In this step (S230), referring to FIG. 10 and FIG. 11, ion implantation is performed to form p type body regions 204, first. Specifically, for example, Al (aluminum) ions are implanted into drift layer 203, thereby forming p type body regions 204, which are the same as p type body regions 4 in the first embodiment. Next, ion implantation is performed to form n⁺ regions 205. Specifically, for example, P (phosphorus) ions are implanted into p type body regions 204, thereby forming n⁺ regions 205, which are the same as n⁺ regions 5 in the first embodiment, within p type body regions 204. The ions can be implanted using a mask layer formed on the main surface of drift layer 203, made of silicon dioxide (SiO₂), and having openings at desired regions for the ion implantations, for example. Further, in IGBT 200, no p⁺ region for fixing the potential of p type body region 204 is formed. As a result, the manufacturing cost can be reduced.

Next, as steps (S240) and (S250), an activation annealing step and a gate oxide film forming step are performed. Referring to FIG. 11 and FIG. 12, these steps (S240) and (S250) are performed in the same manners as steps (S40) and (S50) in the first embodiment. In this way, the impurities introduced in step (S230) are activated and oxide film (gate oxide film) 291 is formed. After this step (S250), a NO annealing step and an Ar annealing step may be performed. These NO annealing step and Ar annealing step may be performed in the same manners as those in the first embodiment.

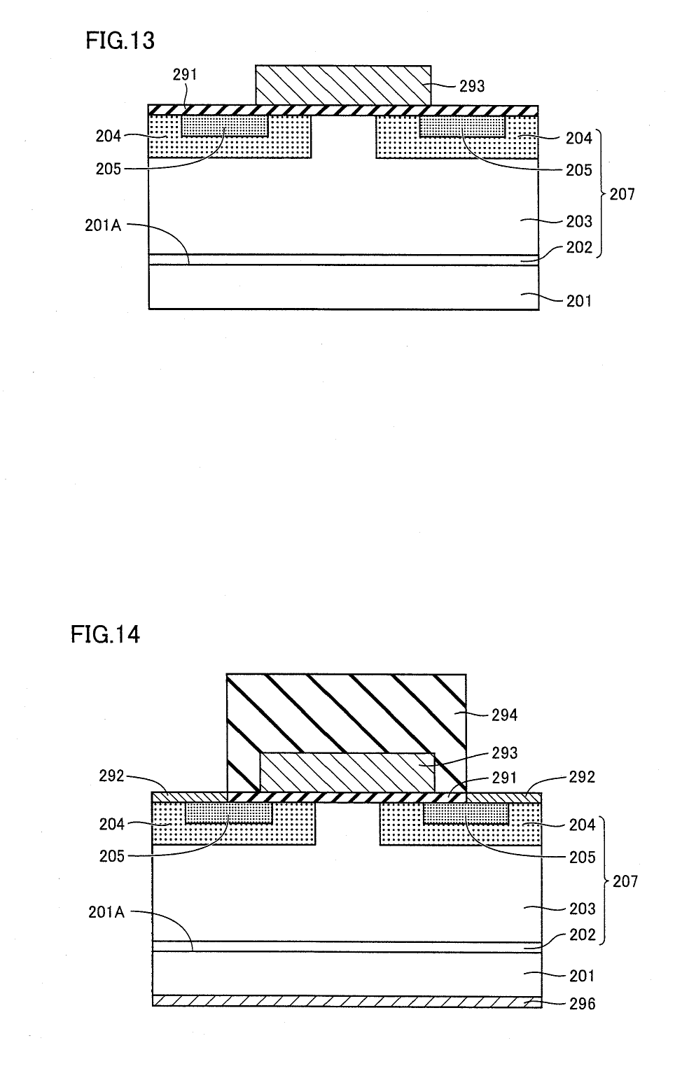

Next, as a step (S260), a gate electrode forming step is performed. In this step (S260), referring to FIG. 12 and FIG. 13, first, the polysilicon film is formed on oxide film 291 using for example the CVD method. Then, a mask layer is formed on the polysilicon film so as to correspond to a desired shape of gate electrode 293. Then, RIE is performed to form gate electrode 293, for example.

Next, as a step (S270), a contact electrode forming step is performed. In this step (S270), referring to FIG. 13 and FIG. 14, interlayer insulating film 294 is first formed as with step (S70) of the first embodiment. Next, instead of titanium film 92A, aluminum film 92B, and silicon film 92C in the first embodiment, a nickel layer is formed and then annealing is provided, thereby forming emitter contact electrodes 292 and collector electrode 296 each made of NiSi. It should be noted that each of emitter contact electrodes 292 and collector electrode 296 is not limited to the one made of NiSi and may be made of, for example, TiAlSi.

Next, as a step (S280), a wire forming step is performed. Then, for example, using the deposition method, emitter wire 295 made of Al that is a conductor is formed to surround interlayer insulating film 294 over main surface 203A and extend to the locations over and on the upper surfaces of n⁺ regions 205 and emitter contact electrodes 292. With the above-described procedure, IGBT 200 in the present embodiment is completed.

A semiconductor device of the present invention is advantageously applicable to a semiconductor device required to achieve both sufficient mobility and reduced manufacturing cost.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a silicon carbide substrate having a main surface having an off angle of not less than 50° and not more than 65° relative to a {0001} plane;
an epitaxial growth layer formed on said main surface;
an insulating film formed on and in contact with said epitaxial growth layer;
a p type body region having p type conductivity and formed to include a region of said epitaxial growth layer, said region being in contact with said insulating film;
an n type contact region having n type conductivity and formed in said p type body region to include a main surface of said epitaxial growth layer opposite to said silicon carbide substrate; and
a contact electrode formed on said epitaxial growth layer in contact with said n type contact region,
said p type body region having a p type impurity density of 5×10¹⁷ cm⁻³ or greater,
said contact electrode and said p type body region being in direct contact with each other.

2. The semiconductor device according to claim 1, wherein said main surface has an off orientation forming an angle of 5° or smaller relative to a <01-10> direction.

3. The semiconductor device according to claim 2, wherein said main surface has an off angle of not less than −3° and not more than 5° relative to a {03-38} plane in the <01-10> direction.

4. The semiconductor device according to claim 1, wherein said main surface has an off orientation forming an angle of 5° or smaller relative to a <−2110> direction.

5. The semiconductor device according to claim 1, wherein said main surface is a surface corresponding to a carbon plane side of silicon carbide constituting said silicon carbide substrate.

6. The semiconductor device according to claim 1, wherein said p type body region has a p type impurity density of 1×10²⁰ cm⁻³ or smaller.

7. The semiconductor device according to claim 1, wherein said p type body region has a p type impurity density of 5×10¹⁸ cm⁻³ or smaller.

8. The semiconductor device according to claim 1, wherein said contact electrode contains at least one element selected from a group consisting of Ti, Al, Si, and Ni.

9. The semiconductor device according to claim 8, wherein said contact electrode is made of TiAlSi, TiAlNi, TiAl, or NiSi.

10. The semiconductor device according to claim 1, wherein a contact resistance between said contact electrode and said n type contact region is 1×10⁻⁴ Ωcm² or smaller.

11. The semiconductor device according to claim 1, wherein a contact resistance between said contact electrode and said p type body region is 1 Ωcm² or smaller.
